(19) United States
(12) Patent Application Publication
(10) Pub. No.: US 2009/0088995 A1
(43) Pub. Date: Apr. 2, 2009

(54) METHOD FOR DETERMINING THE LINEAR ELECTRICAL RESPONSE OF A TRANSFORMER, GENERATOR OR ELECTRICAL MOTOR

(75) Inventors: Martin TIBERG, Geneve (CH); Christoph Heitz, Elgg/ZH (CH); Olaf Hoenecke, Winterthur (CH); Bjorn Gustavsen, Trondheim (NO)

Correspondence Address: BUCHANAN, INGERSOLL & ROONEY PC, POST OFFICE BOX 1404, ALEXANDRIA, VA, 22313-1404, US

(73) Assignee: ABB Technology AG, Zurich (CH)

(21) Appl. No.: 12/328,408

(22) Filed: Dec. 4, 2008

Related U.S. Application Data
(63) Continuation of application No. PCT/CH2006/000303, filed on Jun. 7, 2006.

(51) Int. Cl. G01R 19/00

(52) U.S. Cl. 702/65

(57) ABSTRACT

To characterize an electrical component, namely a medium or high voltage transformer, electrical motor or generator, a two-step procedure is carried out. In a first step, a set of terminal configurations are applied to the terminals (p₁, . . . , pₙ) of the component in order to obtain data describing the linear electrical response of the component to any pattern of voltages uₖ or currents iₖ applied to the terminals (p₁, . . . , pₙ). Typically, such data is e.g. expressed in terms of an admittance matrix Y or impedance matrix Z or, by the set of current and voltage vectors (iₖ, uₖ). Using this data, the linear electrical response of the component 1 under a test terminal configuration can now be calculated in a second step. This procedure allows to determine the response under any desired test terminal configuration without the need to carry out the measurement under the test terminal configuration.

### RELATED APPLICATION

This application claims priority as a continuation application under 35 U.S.C. §120 to PCT/CH2006/000303 filed as an International Application on Jun. 7, 2006 designating the U.S., the entire content of which is hereby incorporated by reference in its entirety.

### TECHNICAL FIELD

A method is disclosed for determining the linear electrical response of a transformer, generator or electrical motor as well as to a use of such a method.

### BACKGROUND INFORMATION

There are various methods to characterize the linear electrical response of transformers, generators or electrical motors. Typically, they include a measurement step under a certain terminal configuration, where the terminals of the component are connected to defined voltage or current sources or impedances or interconnected with each other. Some terminals may also be left unconnected (i.e. connected to an impedance of infinite value). Then, a measurement is carried out, e.g. by determining the voltage at one terminal as a function of the voltage at another terminal.

A typical such technique is the Frequency Response Analysis (FRA), which has evolved as a transformer diagnostic technique for quality control and detection of internal faults, which may not otherwise be detected without opening the transformer and inspecting it by hand and eye. Opening a transformer and emptying the oil therein is very costly and takes long time, whereas FRA is relatively cheap and done within less than one day.

A FRA measurement consists of applying a voltage on one terminal of the transformer (the source terminal) and measuring the voltage output on one of the others (the sink terminal) for a large range of frequencies. The other terminals, which are not source or sink, can either be grounded or left open.

The diagnosis is carried out by studying how the voltage ratio between sink and source varies over the frequency range, and comparing these variations between the phases to check for asymmetries and/or comparing these variations to older records of the same or similar transformers to check for changes over time.

There is no standard specifying exactly how FRA measurements shall be done, even though groups both within IEEE and CIGRE work on such standardisation. Typically, the voltage ratio and sometimes the phase between a source and sink terminal is measured. The number of possible terminal configurations is very large because of the variations in the following parameters:

Type of transformer,

Number of terminals on transformer,

Having the unused terminals open or grounded.

A typical delta-star or star-delta 2-winding transformer has seven terminals: 3 on the HV side, 3 on the LV side and one neutral point. Each of these 7 terminals can be the source terminal and any of the other 6 can be the sink terminal resulting in 42 different combinations and possible measurements. Having the unused terminals both open and grounded doubles the number of measurements. Extra terminals or special configurations, such as having some terminals open and some closed, multiplies the number of measurements further.

This large number of possible terminal configurations make a full characterization of the component cumbersome if not impossible by standard FRA. Therefore, typically, only a subset of the possible terminal configurations are measured, e.g.:

3 on the delta side; connect any two terminals to measure over each winding,

3 on the star side; measure between neutral and each terminal,

3 between HV and LV side for each phase.

These nine measurements often give a good picture of the winding conditions, such that an assessment can be made of the transformer condition. However, there are several important shortcomings of this kind of measurements:

1. It still takes a significant amount of time to reconnect nine times.

2. It happens easily that measurement errors are made when reconnecting. The contact resistance can vary greatly depending on how well the measurement cables are connected to the transformer terminals. Changing the position of the cables between two reconnections can significantly impact the measurement response in the high frequency range.

3. The measurement is incomplete. From just the LV-HV measurements per each phase, you do not see the coupling between the phases, which may reveal important information.

4. Most commercial FRA measurement equipment has 50 Ohm impedance both on the source and sink channel, which is added in series to the transformer measurement and damps the response for low impedances. Thus, impedance variations between say 1-3 Ohm may hardly be seen due to the 50 Ohm impedance in series.

5. Each of the 9 measurements is performed on a different state of the transformer. Consequently, the terminals are alternatively open or terminated with 50 Ohm, which completely changes the transformer state. Even if all non-measured terminals are grounded, the termination is still changed from ground to 50 Ohm on some terminals between each measurement, which invalidates advanced analysis and modeling that assumes that the transformer is a constant well-defined system.

### Further Background Information

From U.S. Pat. No. 4,156,842 a system for measuring the transfer immitances, impedance and admittance, of a linear electrical network having one or more ports is known. The system utilizes clamp-on ferromagnetic cores to electromagnetically couple the transfer immitance measuring system to the electrical network without having to interrupt the normal on-line operation of the electrical network.

GB 2 411 733 describes a method for characterizing a three phase transformer using a single phase power supply.

IEEE Transactions on Energy Conversion, Vol. 9, No. 3, September 1994, page 593ff, discloses a direct maximum-likelihood estimation procedure to identify the synchronous machine models based on the standstill frequency response test data.

### SUMMARY

A method is disclosed, which allows to determine the linear response of a transformer, generator or electrical motor having several terminals, i.e. at least two terminals, in particular at least three terminals, under a given test terminal configuration. The method should have improved ease of use and/or reliability.

A method is disclosed for determining a linear electrical response of a component under at least one test terminal configuration, wherein said component is a transformer, generator or electrical motor comprising several terminals (p₁, . . . , pₙ), said method comprising the steps of step a) applying a set of terminal configurations to said terminals (p₁, . . . , pₙ) to obtain data descriptive of the linear electrical response of said component to any pattern of voltages or currents applied to the terminals (p₁, . . . , pₙ), wherein these measurements are carried out as a function of frequency, wherein the terminal configuration describes a defined state of all terminals of the component, and wherein the set of terminal configurations does not comprise the test terminal configuration, and step b) calculating the response under the test terminal configuration from said data.

### BRIEF DESCRIPTION OF THE DRAWINGS

Further exemplary embodiments, advantages and applications of the disclosure are disclosed in the following description, in reference to the figures, wherein:

FIG. 1 is an example of a transformer to be characterized by the present method,

FIG. 2 shows the component of FIG. 1 connected to a measuring device,

FIG. 3 is a schematic illustration of a component to be characterized,

FIG. 4 is a block circuit diagram of a first exemplary embodiment of a device for a measuring device for characterizing the component,

FIG. 5 is a second exemplary embodiment of a measuring device, and

FIG. 6 is a third exemplary embodiment of a measuring device.

### DETAILED DESCRIPTION

Accordingly, in a first step a), a set of terminal configurations are applied to the terminals of the component in order to obtain data describing the linear electrical response of the component to any pattern of voltages or currents applied to the terminals. Such data is e.g. expressed in terms of an admittance or impedance matrix or, by a set of current and voltage vector pairs as described below.

Using this data, the linear electrical response of the component under the test terminal configuration can now be calculated in a second step b).

This procedure has the advantage that no actual measurement under the test terminal configuration is required. Rather, the measurement can take place under any suitable set of terminal configurations, which allows to choose the most suitable measurement process at hand.

The same data can be used to calculate the response of the component to a plurality of different test configurations.

In a further exemplary embodiment, a measuring device is connected simultaneously to all terminals of the component. The measuring device is adapted to generate the set of terminal configurations and to measure the response of the component to each of these terminal configurations. For example, the measuring device may be equipped to apply different values of voltages, currents and/or impedances to each terminal. This allows to generate the set of terminal configurations without the need to change the cables attached to the component, which increases the accuracy of the measurement.

In particular, such a measuring device can be operated automatically, which allows to increase the measurement speed and reliability.

The linear electrical response at the test terminal configuration can be calculated as the ratio and/or phase shift between two voltages at different terminals, e.g., as a function of frequency. This type of information is used in the so-called frequency response analysis (FRA), which is applied when assessing the status or ageing of a transformer. The present method allows to carry out FRA even if no direct measurement of the ratio and/or phase shift between two voltages at different terminals was made.

An exemplary implementation of step a) comprises an “estimation procedure” in which an estimated admittance matrix Y′ is determined by applying voltages to the terminals of the component and measuring the response of the component. The estimation procedure can e.g. consist of a conventional measurement of the admittance matrix Y′ by applying a voltage to one terminal, grounding all other terminals, measuring the current at each terminal, and repeating this procedure for all terminals. The estimation procedure is followed by a “measurement procedure”, in which several voltage patterns uₖ are applied to the terminals. The voltage patterns correspond to the eigenvectors vₖ of the estimated admittance matrix Y′, wherein “correspond” is to express that the pattern uₖ is substantially (but not necessarily exactly) parallel to the (normalised) eigenvector vₖ corresponding to each eigenvalue λₖ. For each applied voltage pattern uₖ, the response of the component is measured.

As it has been found, applying voltage patterns uₖ corresponding to the eigenvectors vₖ of the admittance matrix Y′ allows to obtain a more accurate description of the component, especially when the eigenvalues λₖ Of the admittance matrix Y′ differ substantially from each other.

The disclosure can be useful for high-voltage or medium-voltage components, i.e. for components suited for operation at voltages exceeding 1 kV.

The method can e.g. be used for characterizing the electrical component. In order to do so, a reference can be provided, e.g. measured at an earlier time (prior to step a) or measured on a reference component, which reference describes the response (the “first response”) of the component under a given test terminal configuration. A measurement according to the present method is then carried out to determine the actual state of the component, and the data from this measurement is used to calculate a “second response” of the component under the test terminal configuration. The first and the second response are then compared for checking the actual status of the component.

### EXEMPLARY EMBODIMENTS OF THE DISCLOSURE

### 1. Definitions

The term “terminal configuration” refers to a defined state of all terminals of the component. The state of a terminal k can be defined by
the current iₖ that is flowing through it (iₖ=0 corresponds to an open terminal) or

the voltage uₖ that is applied to it (uₖ=0 corresponds to a grounded terminal) or

the impedance Zₖ and a voltage φₖ of a voltage source that are connected in series to it, or

the index m of another terminal that the given terminal k is connected to (or a series of indices m₁, m₂, . . . , if terminal k is connected to several other terminals).

### 2. A First Example

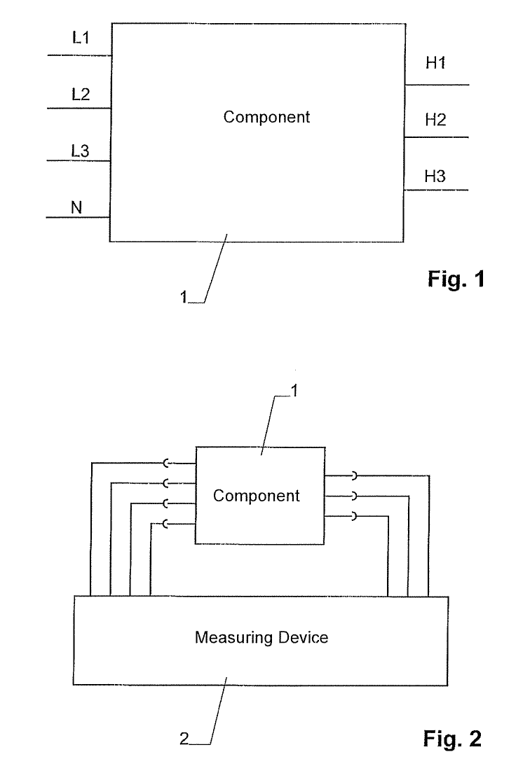

To illustrate the present disclosure, an example thereof is described in the following. This example relates to the characterization and, in particular, to the quality control of a transformer 1 as it is e.g. shown in FIG. 1.

The transformer 1 of FIG. 1 is of the star-delta configuration and has n=7 terminals L1, L2, L3, N, H1, H2, H3.

To characterize transformer 1, a two-step procedure is carried out, namely a measurement step a) and a, calculation step b).

In measurement step a) all seven terminals L1, L2, L3, N, H1, H2, H3 of transformer 1 are connected to a measuring device 2 as shown in FIG. 2. Measuring device 2 comprises, for each terminal L1, L2, L3, N, H1, H2, H3, an adjustable voltage source and/or an adjustable current source and/or an adjustable impedance. Measuring device 2 automatically applies a set of terminal configurations to transformer 1 by repetitively adjusting the voltage sources, current sources and/or impedances. For each terminal configuration, the response of transformer 1 is measured, e.g. by measuring the voltages and currents at all terminals L1, L2, L3, N, H1, H2, H3. In a simple exemplary embodiment, n different terminal configurations are applied, e.g. by applying n different, linearly independent voltage vectors uᵢ (i=1 . . . n) and measuring the corresponding current vectors i (i=1 . . . n). Each such voltage vector uᵢ has n elements (u₁ᵢ, . . . uₙᵢ), and each current vector iᵢ has n elements (i₁ᵢ, . . . iₙᵢ) indicating the voltage uₖᵢ and current iₖᵢ at terminal k in terminal configuration i. The knowledge of the vectors uᵢ and iᵢ for the n terminal configurations allows to estimate the admittance matrix Y from a set of n vector equations

iᵢ=Y·uᵢ (1)

The measurements are carried out as a function of frequency.

It must be noted though that this type of measurement yields inaccurate results only, and a more refined measurement method is described in the section “improved measurement method” below.

In general, the result of measurement step a) is data describing the linear electrical response of the component 1 (such as transformer 1) to any pattern of voltages or currents applied to the terminals L1, L2, L3, N, H1, H2, H3. This data can e.g. be expressed by the admittance matrix Y, the corresponding impedance matrix Z, or by n linearly independent current and voltage vector pairs, each pair describing the voltages and corresponding currents at all terminals L1, L2, L3, N, H1, H2, H3. For reasons explained under the section “improved measurement method” below, the n linearly independent current and voltage vector pairs can be considered to be the most advantageous representation of the data.

In the calculation step b) following measuring step a) the linear electrical response of transformer 1 is calculated for a given test terminal configuration. In general, this test terminal configuration will not be among the set of terminal configurations used in step a) for measuring the component.

For example, when FRA is to be carried out on transformer 1, the test configuration will be a configuration where all except two terminals are grounded (or open). The two terminals are assumed to be terminated by known impedances, such as 50 Ohm. A voltage is applied to one of the two terminals, while the voltage at the other terminal is measured. In other words, the test terminal configuration corresponds to a typical FRA measurement terminal configuration. However, instead of carrying out an actual measurement at the test terminal configuration, the result of such a measurement is simulated by calculating the component's behavior from the data obtained in step a).

The calculated result can then e.g. be used to determine the ratio and/or voltage phase difference between two terminals as a function of frequency to obtain a graph as used in FRA.

For example, to calculate the response of an FRA measurement, where the first terminal (e.g. L1 in FIG. 1) is the source, the fourth terminal (e.g. H1 in FIG. 1) is the sink, and all the other terminals L2, L3, N, H2, H3 are open, and the first and fourth terminal are terminated with a R₁=R₄=50 Ohm impedance, the current vector i is given by

$$i = ( \begin{matrix}{i}_{1} \\ 0 \\ 0 \\ - {u}_{4} / {R}_{4} \\ 0 \\ 0\end{matrix} ) \qquad ( 2 )$$

The FRA response u₄/u₁ is straight-forward to calculate from the relationship

$$( \begin{matrix}{i}_{1} \\ 0 \\ 0 \\ - {u}_{4} / {R}_{4} \\ 0 \\ 0 \\ 0\end{matrix} ) = ( \begin{matrix}{y}_{11} & {y}_{12} & … & … & … & … & … \\ {y}_{21} & … & … & … & … & … & … \\ … & … & … & … & … & … & … \\ … & … & … & … & … & … & … \\ … & … & … & … & … & … & … \\ … & … & … & … & … & … & … \\ … & ⋯ & ⋯ & ⋯ & ⋯ & ⋯ & {y}_{77}\end{matrix} ) ( \begin{matrix}{u}_{1} \\ … \\ … \\ {u}_{4} \\ … \\ … \\ …\end{matrix} ) , \qquad ( 3 )$$

with yᵢⱼ being components of the admittance matrix Y.

The easiest way to proceed is to multiply both sides of the equation (3) with the impedance matrix Z=Y⁻¹ and then to reduce the system of equations to just the first and fourth row. Then there are three unknowns, u₁, u₄ and i₁, and two equations. Since we are interested in the complex ratio u₄/u₁ (i.e. ratio of the voltage amplitudes as well as their mutual phase shift), the unknowns are further reduced to two, and we get the following result:

$$\frac{{u}_{4}}{{u}_{1}} = \frac{{R}_{4} \cdot {z}_{41}}{{z}_{11} ( {z}_{44} + {R}_{4} ) - {z}_{41} {z}_{14}} , \qquad ( 4 )$$

with zᵢⱼ being the components of the impedance matrix Z.

If the same FRA with the unused terminals L2, L3, N, H2, H3 being grounded instead of being open were to be calculated, their terminal configurations would just change from iₓ=0 to uₓ=0, yielding the expression

$$\frac{{u}_{4}}{{u}_{1}} = - \frac{{R}_{4} \cdot {y}_{41}}{1 + {R}_{4} \cdot {y}_{44}} \qquad ( 5 )$$

Once the data is obtained in step a), the response of the component 1 under any test configuration can be calculated. In particular, the response of the component 1 under several test configurations (e.g. under the nine configurations typically used for FRA) can be calculated easily and quickly.

### 3. General Applications:

In the first exemplary embodiment above, the application of the present method for FRA measurements on a transformer 1 having seven terminals L1, L2, L3, N, H1, H2, H3 has been described. It must be noted, though, that the method can be used for numerous other applications. In particular:

Instead of using the method on a transformer 1, the component 1 under test may also be an electrical generator and/or an electrical motor.

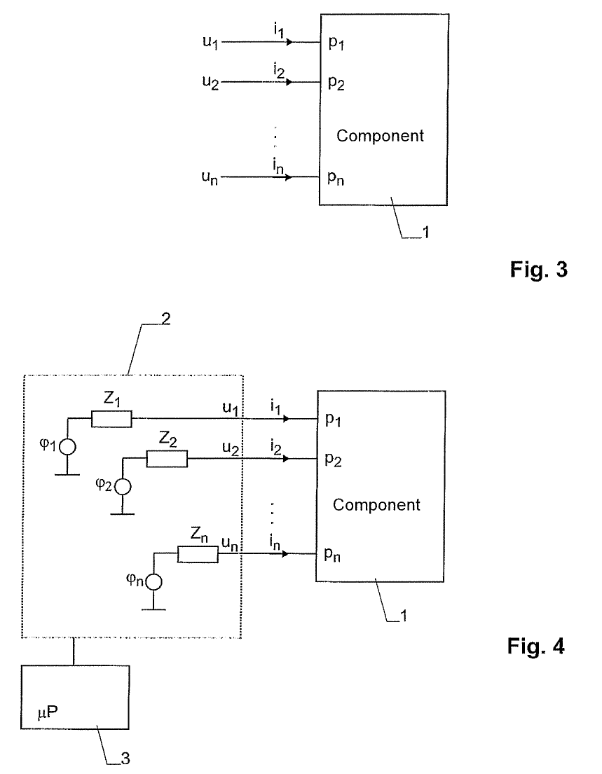

In general, the number n of terminals p₁, . . . , pₙ (FIGS. 3, 4) of the component 1 may vary, and e.g. be three (e.g. for a three-phase motor in delta configuration) or four (e.g. for a three phase generator in star configuration or for a one phase transformer). The present method is in particular useful for components 1 with more than two terminals p₁, . . . , pₙ, where there is a potentially large number of different terminal configurations.

The present method can be used for various purposes. A typical application is quality control, e.g. by using FRA as described above, or by simulating other measurements using the data obtained in measurement step a). Another application is network modeling: Some network models require the measurement of the linear response of a component 1 under certain given terminal configurations—the present method can obviate the need to actually carry out these measurements by using the data from measurement step a) in order to calculate the response under the given terminal configurations.

### 4. Improved Measurement Method

This section describes an improved method for obtaining the data in measurement step a).

FIG. 3 shows a multi-terminal component 1 having n>1 terminals p₁ through pₙ, which may be a transformer, electrical motor or generator. When linear voltages u₁ through uₙ are applied to the terminals p₁ through pₙ, currents i₁ through iₙ will flow. The linear electrical response of component 1 is characterized by its admittance matrix Y or, equivalently, by its impedance matrix Z. In admittance notation, applying the voltage vector u=(u₁ . . . uₙ) of voltages at the terminals p₁ through pₙ generates a current vector i=(i₁ . . . iₙ) as follows:

i=Y·u. (11)

The general principle of the improved measurement method is based on an estimation procedure and a measurement procedure. In the estimation procedure, an estimated admittance matrix Y′ is determined, in the measurement procedure a more accurate measurement is carried out.

In the estimation procedure, the elements of the estimated admittance matrix Y′ can e.g. be measured directly using conventional methods. The diagonal elements Y′ᵢᵢ can e.g. by measured by applying a voltage uᵢ to terminal pᵢ and measuring the current iᵢ at the same terminal pᵢ while all other terminals are short-circuited to zero volt, i.e. Y′ᵢᵢ=iᵢ/uᵢ while uⱼ=0 for i≠j. The other elements Y′ᵢⱼ of the matrix can be measured by applying a voltage uᵢ at terminal pᵢ while setting all other terminals to zero volt and measuring the current iⱼ at terminal pⱼᵢ, Y′ᵢⱼ=iⱼ/uᵢ while uⱼ=0 for i≠j.

Other conventional methods for measuring the estimated impedance matrix Y′ in the estimation procedure can be used as well.

In general, the estimated admittance matrix Y′ has n eigenvalues λ₁ . . . λₙ and n corresponding to (normalised) eigenvectors v₁ . . . vₙ for which

Y′·vₖ=λₖ·vₖ (12)

Once the estimated admittance matrix Y′ is known, its eigenvectors vₖ can be calculated.

In a measurement procedure following the estimation procedure, several (in general n) voltage patterns uₖ=(u₁ₖ . . . uₙₖ) are applied to terminals p₁ . . . pₙ Of component 1. Each voltage pattern uₖ corresponds to one of the eigenvectors vₖ. For each applied voltage pattern uₖ, a response of the component 1 is measured, in particular by measuring the induced current pattern iₖ.

As mentioned above, voltage pattern uₖ corresponds to the (normalised) eigenvector vₖ (which is one of the n normalised eigenvectors of the admittance matrix), namely in the sense that the voltage pattern uₖ is substantially parallel to the eigenvector vₖ corresponding to eigenvalue λₖ. Theoretically, using uₖ cc vₖ would be the best solution, but a measuring device 2, 3 generating the voltage patterns uₖ will, in general, not be able to generate voltage patterns matching the eigenvectors vₖ exactly due to discretisation errors. Methods for handling devices 2, 3 with limited resolution for generating the voltage patterns will be addressed below.

Once the measurement procedure is complete, the voltage patterns uₖ and the corresponding current patterns iₖ, i.e. a set of n voltage and current vector pairs uₖ, iₖ, fully characterizes the linear response of the component 1.

In general, the admittance matrix Y is frequency dependent. Hence, in many applications, the linear electrical response of component 1 should be known for an extended frequency range, e.g. from 50 Hz to more than 500 kHz. For this reason, the estimation procedure is carried out at a plurality of frequencies ωᵢ in the given frequency range. For each estimation procedure, the eigenvalues λₖ(ωᵢ) at the given frequency ωᵢ are calculated. Then, the most critical frequencies are determined, which are those frequencies where the eigenvalues λₖ(ωᵢ) reach a local maximum or minimum or, in particular, where the absolute ratio between the largest and smallest eigenvalue has a maximum or exceeds a given threshold. These critical frequencies are of particular interest, either because they are indicative of a resonance of component 1 or because they show that some of the estimated eigenvalues may be of poor accuracy and the described measurement procedure is required to increase the accuracy.

It is principally possible to divide the desired frequency range into a number of frequency windows and to calculate the most critical frequencies in each frequency window.

For each or at least some of the critical frequencies, the measurement procedure described above is carried out to refine the measurement. In addition or alternatively thereto, the measurement procedure can be carried out at other points within the frequency range of interest.

The frequencies ωᵢ where measurements are carried out can be distributed linearly or logarithmically over the range of frequencies of interest. In an exemplary embodiment, though, the density of measurement frequencies ωᵢ close to the critical frequencies as mentioned above is larger than the density of measurement frequencies ωᵢ in spectral regions far away from the critical frequencies. This allows to obtain a more reliable characterization of the component 1.

4.1 The Measuring Device:

A general measuring device 2, 3 for carrying out the improved measurement method is disclosed in FIG. 4. In a most general case, measuring device 2, 3 comprises n adjustable voltage sources generating voltages φ₁ to φₙ, which are fed to the terminals p₁ to pₙ through impedances Z₁ to Zₙ. The voltages φ₁ to φₙ all have equal frequency and known phase relationship. The impedances Z₁ through Zₙ may be practically zero or, as described below, they may be adjustable and potentially non-zero. A control unit 3 is provided for automatically adjusting the voltage sources and, where applicable, the impedances Z₁ to Zₙ.

For the device of FIG. 4 we have

φ=u+D·i, (13)

where φ=(φ₁ . . . φₙ) are the voltages of the voltage sources, u=(u₁ . . . uₙ) the input voltages at the terminals p₁, . . . , pₙ, and D is a diagonal matrix with the diagonal elements Z₁ to Zₙ.

Combining equations (11) and (13) gives the following relationship between the input voltages u and the applied voltages φ:

u=(I+D·Y)⁻¹·φ. (14)

where I is the n×n identity matrix.

As mentioned above, the applied voltages u should correspond to the eigenvalues vₖ of the estimated admittance matrix Y′. In general, however, it will not be possible to match this condition exactly, because the voltage sources will not be able to generate any arbitrary voltage values, but only a discrete set of values. If the number of voltage values that can be generated is small, the impedances Z₁ to Zₙ can be designed to be adjustable as well in order to obtain a larger number of different input voltages u.

The input voltage vector uₖ can be expressed as a linear combination of the eigenvalues vᵢ, i.e.

$${u}_{k} = {\sum }_{i = 1}^{n} {α}_{i} {v}_{i} . \qquad ( 15 )$$

with coefficients αᵢ. Combining equations (15), (11) and (12) yields

$$i = {\sum }_{i = 1}^{n} {λ}_{i} {α}_{i} {v}_{i} . \qquad ( 5 )$$

Hence, in order to maximise the influence of the k-th eigenvalue λₖ on the input current vector i in proportion to the other eigenvalues, the following error function must be minimised

$$\frac{{\sum }_{i = 1}^{n} {( {λ}_{i} {α}_{i} )}^{2} - {( {λ}_{k} {α}_{k} )}^{2}}{{( {λ}_{k} {α}_{k} )}^{2}} . \qquad ( 16 )$$

In other words, for each eigenvalue λₖ, the coefficients α₁ . . . αₙ must be found (among the set of possible coefficients, which is a finite set due to the discretisation inherent to measuring device 2) for which the term of equation (16) is smallest.

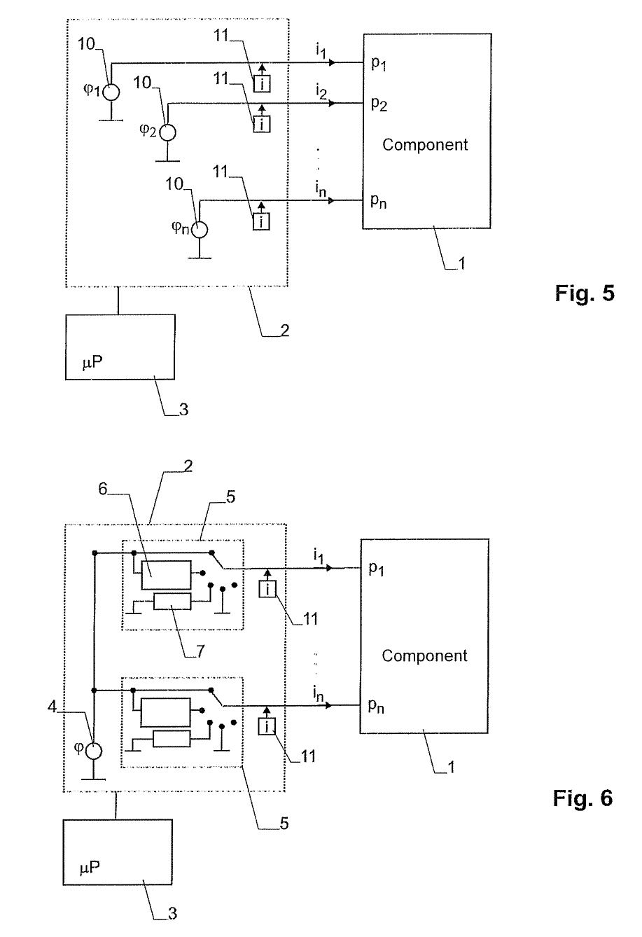

If measuring device 2 has adjustable voltage sources and impedances as shown in FIG. 5, we have

α=[v₁ . . . vₙ]⁻¹·(I+D·Y′)⁻¹·φ (17)

A measuring device 2, 3 for carrying out the above method should, in general, comprise n voltage generators 10 that are programmable to apply the voltage pattern u to the n terminals of the component 1 undre test. Further, it should comprise n current sensors 11 to measure the currents i. It should be adapted to apply at least n suitable voltage patterns u to the terminals p₁, . . . , pₙ consecutively for measuring the linear response of the component 1 automatically. This is especially advantageous for components 1 having more than two terminals p₁, . . . , pₙ, because using this kind of automatic measurement on components 1 with n>2 terminals p₁, . . . , pₙ provides substantial gains in speed and accuracy while reducing the costs.

The measuring device 2, 3 can comprise a control unit 3 for carrying out the measurement using the estimation and measurement procedures outlined above.

One exemplary embodiment of a measuring device 2, 3 is shown in FIG. 5. In this device 2, 3, a voltage generator 10 for generating an individual voltage pᵢ of adjustable amplitude and phase is provided for each input terminal p₁, . . . , pₙ. It also comprises n current sensors 11, one for measuring the current to/from each terminal p₁, . . . , pₙ. Control unit 3 is able to set the applied input voltage u directly by controlling the voltage generators by each voltage generator 10 is small, an optimum voltage for a given eigenvector vₖ can be calculated by minimising the term of equation (16). For each applied voltage pattern uₖ, control unit 3 measures the currents through the terminals p₁, . . . , pₙ by means of the current sensors 11.

Another exemplary embodiment of a measuring device is shown in FIG. 6. This device comprises a single voltage source 4 only. The voltage φ from the voltage source 4 is fed to n voltage converters 5 controlled by control unit 3, the voltage source 4 and voltage converters 5 being used instead of the voltage generators 10 of the previous exemplary embodiment. Each voltage converter 5 selectively connects one terminal p₁, . . . , pₙ to either the voltage φ directly, to the voltage φ through a damping circuitry 6, to ground via an impedance 7, to ground directly, or leaves the terminal p₁, . . . , pₙ open (infinite impedance). This measuring circuit has the advantage that it requires a single voltage source 4 only. Suitable settings of the voltage converters for each value can be calculated form equations (16) and (17).

Further Processing of the Results:

As mentioned above, the described improved measurement procedure yields, for a given frequency, a set of voltage patterns uₖ and the corresponding current patterns iₖ, which fully characterize the linear response of component 1 at the given frequency.

The values uₖ and iₖ for k=1 . . . n can, in principle, be converted into a more accurate estimate of the admittance matrix Y or the corresponding impedance matrix Z. However, if the smallest and largest eigenvalues of admittance matrix Y differ by several orders of magnitude, such a matrix Y is difficult to process numerically with floating point calculations due to rounding errors and limited accuracy of the numerical algorithms. Hence, in an exemplary embodiment of the present disclosure, the vector pairs uₖ and iₖ are used directly for further processing, without prior conversion to an admittance matrix Y or impedance matrix Z.

For example, the results of the measurement procedure can e.g. be used for FRA as described above or for modeling the electrical properties the component 1 or of a network that component 1 is part of. Such a model can e.g. be used to analyse the stability of the network in general or its response to given events in particular.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMBERS

1 component under test
2 measuring device
3 control unit, part of measuring device
4 single voltage source
5 voltage converter
6 damping circuit
7 impedance
10 voltage generator
11 current sensor

What is claimed is:

1. A method for determining a linear electrical response of a component under at least one test terminal configuration, wherein said component is a transformer, generator or electrical motor comprising several terminals (p₁, . . . , pₙ), said method comprising the steps of
step a) applying a set of terminal configurations to said terminals (p₁, . . . , pₙ) to obtain data descriptive of the linear electrical response of said component to any to pattern of voltages or currents applied to the terminals (p₁, . . . , pₙ), wherein these measurements are carried out as a function of frequency, wherein the terminal configuration describes a defined state of all terminals of the component, and wherein the set of terminal configurations does not comprise the test terminal configuration, and
step b) calculating the response under the test terminal configuration from said data.

2. The method of claim 1, wherein step b) comprises the calculation of the response of the component under a plurality of different test terminal configurations.

3. The method of claim 1, wherein said step a) comprises the step of simultaneously connecting a multitude of the terminals (p₁, . . . , pₙ), in particular all of the terminals (p₁, . . . , pₙ), of said component to a measuring device, which is adapted to generate said set of terminal configurations, and to measure the response of said component to said terminal configurations.

4. The method of claim 3, wherein said measuring device comprises, for each terminal (p₁, . . . , pₙ) ,
an adjustable voltage source, and/or
an adjustable current source, and/or
an adjustable impedance (Z₁, . . . , Zₙ) ,
wherein said set of terminal configurations is generated by adjusting said voltage sources, current sources and/or impedances (Z₁, . . . , Zₙ), respectively.

5. The method of claim 3, wherein said voltage sources, current sources and/or impedances (Z₁, . . . , Zₙ) are adjusted automatically under control of said measuring device.

6. The method of claim 1, wherein said step b) comprises the step of calculating a voltage ratio and/or voltage phase difference between two different terminals (p₁, . . . , pₙ).

7. The method of claim 6, wherein said step b) comprises the step of calculating a voltage ratio and/or voltage phase difference between two different terminals (p₁, . . . , pₙ) as a function of frequency.

8. The method of claim 1, wherein said component has more than two terminals (p₁, . . . , pₙ).

9. The method of claim 1, wherein said component is a high-voltage or medium-voltage device.

10. The method of claim 1, wherein said data comprises a set of N linearly independent current and voltage vector pairs iₖ, uₖ, each pair describing the voltages and corresponding currents at said terminals (p₁, . . . , pₙ), wherein N is the number of terminals (p₁, . . . , pₙ) being measured of said component.

11. The method of claim 1, wherein said data is descriptive of the linear electrical response of said component over a frequency range between less than 100 Hz and more than 500 kHz.

12. The method of claim 1, wherein said step a) comprises
an estimation procedure comprising the step of determining an estimated admittance matrix Y′ of said component by applying voltages to said terminals (p₁, . . . , pₙ) and measuring a response of said component and
a measurement procedure comprising the step of applying several voltage patterns uₖ to the terminals (p₁, . . . , pₙ) of said component, each voltage pattern uₖ corresponding to an, eigenvector vₖ of said estimated admittance matrix Y′, and determining, for each applied voltage pattern uₖ, a response of said component.

13. The method of claim 12, wherein said voltage patterns uₖ are generated by means of a measuring device capable of applying a discrete set of different voltage patterns uₖ to said terminal (p₁, . . . , pₙ), wherein each voltage pattern uₖ corresponds to that member of said set that has the property that the term
$$\frac{{\sum }_{i = 1}^{n} {( {λ}_{i} {α}_{i} )}^{2} - {( {λ}_{k} {α}_{k} )}^{2}}{{( {λ}_{k} {α}_{k} )}^{2}}$$
is minimal, wherein λ₁, . . . , λₙ are n eigenvalues of the estimated admittance matrix Y′ and
$${u}_{k} = {\sum }_{i = 1}^{n} {α}_{i} {v}_{i}$$
with coefficients αᵢ.

14. A use of the method of claim 1 for characterizing said component by the steps of
providing a reference describing a first response of said component at said test terminal configuration, using said step a) to measure an actual state of said component, and
using said step b) to calculate a second response at said test terminal configuration, and
comparing said first and said second response.

15. The use of claim 14, wherein said reference was derived from a measurement carried out prior to said step a).

16. The method of claim 2, wherein said step a) comprises the step of simultaneously connecting a multitude of the terminals (p₁, . . . , pₙ), in particular all of the terminals (p₁, . . . , pₙ), of said component to a measuring device, which is adapted to generate said set of terminal configurations, and to measure the response of said component to said terminal configurations.

17. The method of claim 4, wherein said voltage sources, current sources and/or impedances (Z₁, . . . , Zₙ) are adjusted automatically under control of said measuring device.

18. The method of claim 5, wherein said step b) comprises the step of calculating a voltage ratio and/or voltage phase difference between two different terminals (p₁, . . . , pₙ).

19. The method of claim 7, wherein said component has more than two terminals (p₁, . . . , pₙ).

20. The method of claim 8, wherein said component is a high-voltage or medium-voltage device.

21. The method of claim 9, wherein said data comprises a set of N linearly independent current and voltage vector pairs iₖ, uₖ, each pair describing the voltages and corresponding currents at said terminals (p₁, . . . , pₙ) wherein N is the number of terminals (p₁, . . . , pₙ) being measured of said component.

22. The method of claim 10, wherein said data is descriptive of the linear electrical response of said component over a frequency range between less than 100 Hz and more than 500 kHz.

23. The method of claim 11, wherein said step a) comprises
an estimation procedure comprising the step of determining an estimated admittance matrix Y′ of said component by applying voltages to said terminals (p₁, . . . , pₙ) and measuring a response of said component and
a measurement procedure comprising the step of applying several voltage patterns uₖ to the terminals (p₁, . . . , pₙ) of said component, each voltage pattern uₖ corresponding to an eigenvector vₖ of said estimated admittance matrix Y′, and determining, for each applied voltage pattern uₖ, a response of said component.

24. A use of the method of claim 13 for characterizing said component by the steps of
providing a reference describing a first response of said component at said test terminal configuration, using said step a) to measure an actual state of said component, and
using said step b) to calculate a second response at said test terminal configuration, and
comparing said first and said second response.
